(19) United States
(12) Patent Application Publication
(10) Pub. No.: US 2017/0292992 A1
(43) Pub. Date: Oct. 12, 2017

(54) SEMICONDUCTOR TESTS USING INTERPOSERS, AND ASSOCIATED SYSTEMS AND METHODS

(71) Applicant: Translarity, Inc., Fremont, CA (US)

(72) Inventors: Christopher T. Lane, Los Gatos, CA (US); Douglas A. Preston, McMinnville, OR (US)

(21) Appl. No.: 15/096,862

(22) Filed: Apr. 12, 2016

(51) Int. Cl. G01R 31/28; G01R 1/04

(52) U.S. Cl. CPC G01R 31/2891; G01R 31/2889; G01R 1/0466

(57) ABSTRACT

Semiconductor tests that use an interposer, and associated systems and methods. In one embodiment, an apparatus for testing semiconductor dies includes a wafer translator having a wafer-side positioned to face toward a device under test, and an inquiry-side facing away from the wafer side. A wafer translator chuck is configured to carry the wafer translator and the wafer-side of the wafer translator in a curved orientation.

### TECHNICAL FIELD

The present technology is directed generally to semiconductor wafer tests. In particular, test signals are transmitted through interposers that have contact pads with a relatively small scale facing a wafer, and contact pads with a relatively large scale facing associated test equipment.

### BACKGROUND

Integrated circuits are used in a wide variety of products. Integrated circuits have continuously decreased in price and increased in performance, becoming ubiquitous in modern electronic devices. These improvements in the performance/cost ratio are based, at least in part, on miniaturization, which enables more semiconductor dies to be produced from a wafer with each new generation of the integrated circuit manufacturing technology. Furthermore, the total number of the signal and power/ground contacts on a semiconductor die generally increases with new, more complex die designs.

Prior to shipping a semiconductor die to a customer, the performance of the integrated circuits is tested, either on a statistical sample basis or by testing each die. An electrical test of the semiconductor die typically includes powering the die through the power/ground contacts, transmitting signals to the input contacts of the die, and measuring the resulting signals at the output contacts of the die. Therefore, during the electrical test at least some contacts on the die must be electrically contacted to connect the die to sources of power and test signals.

Conventional test contactors include an array of contact pins attached to a substrate, e.g., a relatively stiff printed circuit board (PCB). In operation, the test contactor is pressed against a wafer such that the array of contact pins makes electrical contact with the corresponding array of die contacts (e.g., pads or solderballs) on the dies of the wafer. Next, a wafer tester sends electrical test sequences (e.g., test vectors) through the test contactor to the input contacts of the dies of the wafer. In response to the test sequences, the integrated circuits of the tested die produce output signals that are routed through the test contactor back to the wafer tester for analysis and to determine whether a particular die passes the test.

In general, an increasing number of die contacts that are distributed over a decreasing area of the die results in smaller contacts spaced apart by smaller distances (e.g., a smaller pitch). Furthermore, a characteristic diameter of the contact pins of the test contactor generally scales with a characteristic dimension of the contact structures on the semiconductor die or the package. Therefore, as the contact structures on the die become smaller and/or have a smaller pitch, the contact pins of the test contactors become smaller, too. However, it is difficult to significantly reduce the diameter and pitch of the contact pins, e.g., because of the difficulties in machining and assembling such small parts, resulting in low yield and inconsistent performance from one test contactor to another. Furthermore, precise alignment between the test contactor and the wafer is difficult because of the relatively small size/pitch of the contact structures on the wafer. Accordingly, there remains a need for cost effective test contactors that can scale down in size with the size and pitch of the contact structure on the die.

### BRIEF DESCRIPTION OF THE DRAWINGS

Many aspects of the present disclosure can be better understood with reference to the following drawings. The components in the drawings are not necessarily to scale. Instead, emphasis is placed on clearly illustrating the principles of the present disclosure. Furthermore, in the drawings, like reference numerals generally designate corresponding parts throughout the several views.

FIG. 1A is an exploded view of a portion of a test stack for testing semiconductor wafers in accordance with an embodiment of the presently disclosed technology.

FIG. 1B is a partially schematic, top view of a wafer translator configured in accordance with an embodiment of the presently disclosed technology.

FIG. 1C is a partially schematic, bottom view of a wafer translator configured in accordance with an embodiment of the presently disclosed technology.

FIGS. 2A-2C are side, cross-sectional views of a test stack for testing semiconductor wafers in accordance with an embodiment of the presently disclosed technology.

FIG. 3 is a partially schematic, bottom view of a wafer translator chuck configured in accordance with another embodiment of the presently disclosed technology.

FIG. 4 is a partially schematic, side view of a translator stack configured in accordance with an embodiment of the presently disclosed technology.

FIG. 5 is a graph of the vacuum between a wafer translator and a wafer chuck as a function of time in accordance with an embodiment of the presently disclosed technology.

### DETAILED DESCRIPTION

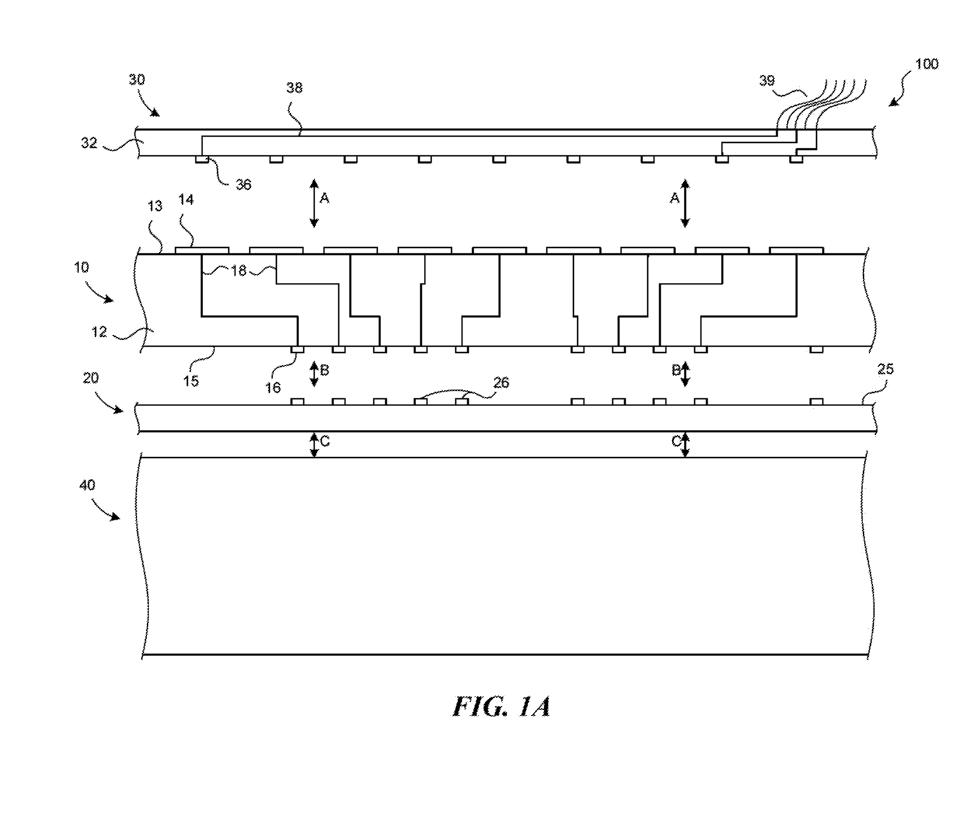

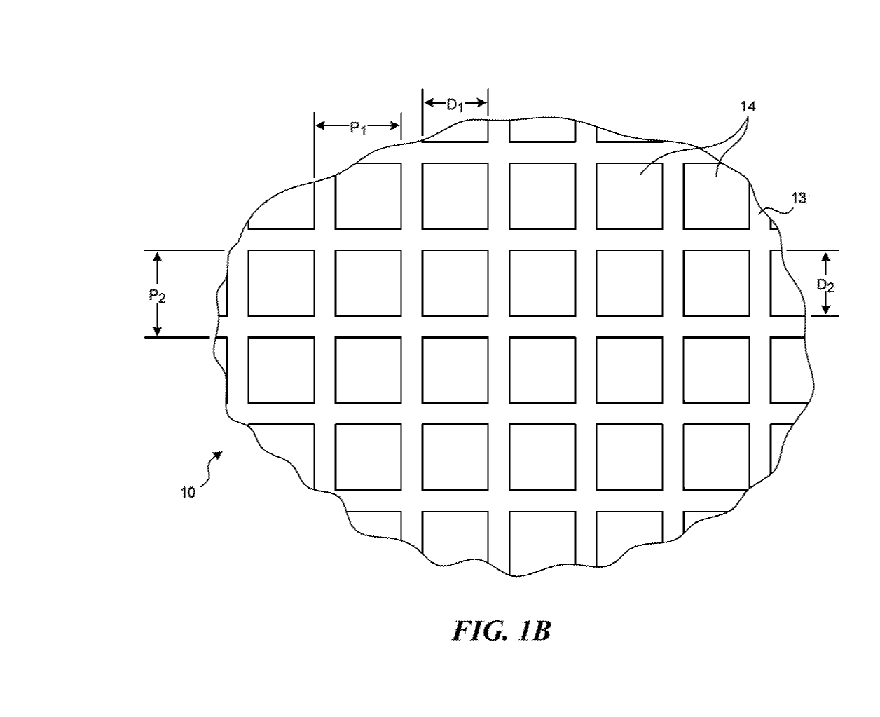

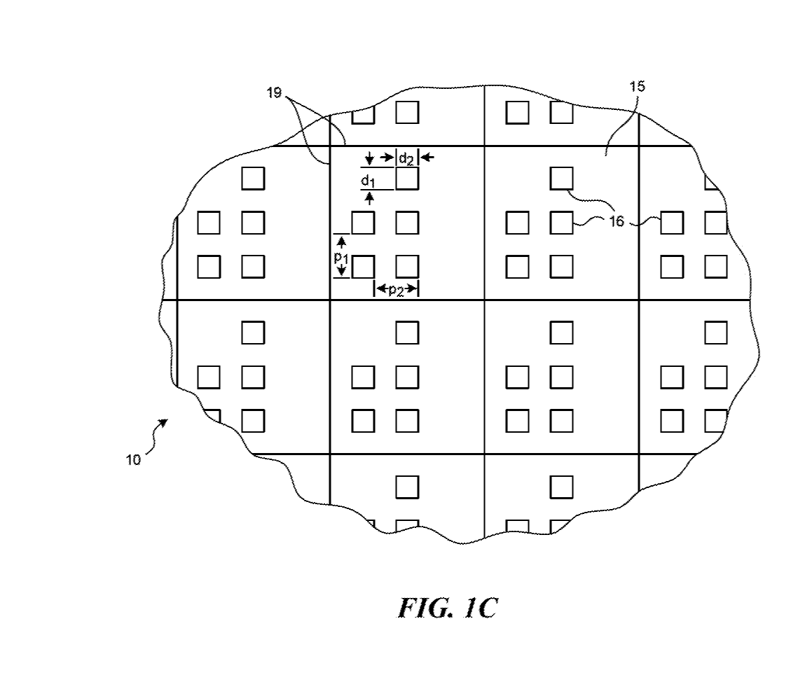

Specific details of several embodiments of representative wafer translators and associated methods for use and manufacture are described below. The wafer translators can be used for testing semiconductor dies on a wafer. The semiconductor dies may include, for example, memory devices, logic devices, light emitting diodes, micro-electro-mechanical-systems, and/or combinations of these devices. A person skilled in the relevant art will also understand that the technology may have additional embodiments, and that the technology may be practiced without several of the details of the embodiments described below with reference to FIGS. 1A-5.

Briefly described, methods and devices for testing dies on the semiconductor wafers are disclosed. The disclosed methods and systems enable operators to test devices having pads, solderballs and/or other contact structures having small sizes and/or pitches. Solderballs, pads and/or other suitable conductive elements on the dies are collectively referred to herein as “contact structures” or “contacts.” In many embodiments, the technology described in the context of one or more types of contact structures can also be applied to other contact structures.

In some embodiments, a wafer-side of the wafer translator carries the wafer-side contact structures having relatively small sizes and/or pitches (collectively, “scale”). The wafer-side contact structures of the wafer translator are electrically connected to corresponding inquiry-side contact structures having relatively larger sizes and/or pitches at the opposite, inquiry-side of the wafer translator. Therefore, once the wafer-side contact structures are properly aligned to contact the semiconductor wafers, the larger size/pitch of the opposing inquiry-side contact structures enable more robust contact (e.g., requiring less precision). The larger size/pitch of the inquiry-side contact structures may provide more reliable contact and be easier to align against the pins of the test contactor.

In at least some embodiments, undesirable gas bubbles can be trapped between the wafer translator and the wafer. In some embodiments, e.g., when the wafer translator is not rigid, an elastomer, which can be controlled so as to be curved, can be inserted between a wafer translator chuck and the wafer translator to bend the central areas of the wafer translator, thus promoting a desired sequence of contacting the wafer by specific areas of the wafer translator. For example, if the wafer translator is deliberately curved (e.g., bowed), a central portion of the wafer translator may contact the wafer first, with the radially peripheral portions of the wafer translator contacting the wafer subsequently. Such a sequence of contacting the wafer (e.g., from the center in an outward direction) can minimize or at least reduce trapping gas bubbles between the wafer translator and the wafer. In some embodiments, a segmented wafer translator chuck capable of independently moving segments of the translator (e.g., a central segment and radial ring segments) can be used to control the sequence of contact between the wafer translator and the wafer.

Many embodiments of the technology described below may take the form of computer- or controller-executable instructions, including routines executed by a programmable computer or controller. Those skilled in the relevant art will appreciate that the technology can be practiced on computer/controller systems other than those shown and described below. The technology can be embodied in a special-purpose computer, controller or data processor that is specifically programmed, configured or constructed to perform one or more of the computer-executable instructions described below. Accordingly, the terms “computer” and “controller” as generally used herein refer to any data processor and can include Internet appliances and hand-held devices (including palm-top computers, wearable computers, cellular or mobile phones, multi-processor systems, processor-based or programmable consumer electronics, network computers, mini computers and the like). Information handled by these computers can be presented at any suitable display medium, including a CRT display or LCD.

The technology can also be practiced in distributed environments, where tasks or modules are performed by remote processing devices that are linked through a communications network. In a distributed computing environment, program modules or subroutines may be located in local and remote memory storage devices. Aspects of the technology described below may be stored or distributed on computer-readable media, including magnetic or optically readable or removable computer disks, as well as distributed electronically over networks. Data structures and transmissions of data particular to aspects of the technology are also encompassed within the scope of the embodiments of the technology.

FIG. 1A is an exploded view of a portion of a test stack 100 for testing semiconductor wafers in accordance with an embodiment of the presently disclosed technology. The test stack 100 can route signals and power from a tester (not shown) to a wafer or other substrate carrying one or more devices under test (DUTs), and transfer the output signals from the DUTs back to the tester for analysis and determination about an individual DUT's performance (e.g., whether the DUT is suitable for packaging and shipment to the customer). The DUT can be a single silicon die or multiple silicon dies (e.g., when using a parallel test approach). The signals and power from the tester can be routed through a test contactor 30 to a wafer translator 10, and further to the semiconductor dies on the wafer 20.

In some embodiments, the signals and power can be routed from the tester to the test contactor 30 using cables 39. Conductive traces 38 carried by a test contactor substrate 32 can electrically connect the cables 39 to contacts 36 on the opposite side of the test contactor substrate 32. In operation, the test contactor 30 can contact an inquiry-side 13 of a wafer translator 10 as indicated by arrows A. In at least some embodiments, relatively large inquiry-side contact structures 14 can improve aligning with the corresponding contacts 36 of the test contactor 30. The contact structures 14 are electrically connected with relatively small wafer-side contact structures 16 on a wafer-side 15 of the translator 10 through conductive traces 18 of a wafer translator substrate 18. The size and/or pitch of the wafer-side contact structures 16 are suitable for contacting corresponding die contacts 26 of the wafer 20. In some embodiments, arrows B indicate a movement of the wafer translator 10 to make contact with an active side 25 of the wafer 20. As explained above, the signals and power from the tester can test the DUTs of the wafer 20, and the output signals from the tested DUTs can be routed back to the tester for analysis and a determination as to whether the DUTs are suitable for packaging and shipment to the customer.

The wafer 20 can be supported by a wafer chuck 40. Arrows C indicate the direction of the wafer 20 mating with the wafer chuck 40. In operation, the wafer 20 can be held against the wafer chuck 40 using, e.g., vacuum or mechanical clamping.

FIGS. 1B and 1C are partially schematic, top and bottom views, respectively, of a wafer translator configured in accordance with embodiments of the presently disclosed technology. FIG. 1B illustrates the inquiry-side 13 of the wafer translator 10. Distances between the adjacent inquiry-side contact structures 14 (e.g., pitch) are denoted P₁ in one direction and P₂ in other direction. The illustrated inquiry-side contact structures 14 have a width D₁ and a height D₂. Depending upon the embodiment, the inquiry-side contact structures 14 may be squares, rectangles, circles or other shapes. Furthermore, the inquiry-side contact structures 14 can have a uniform pitch (e.g., P₁ and P₂ being equal across the translator 10) or a non-uniform pitch.

FIG. 1C illustrates the wafer-side 15 of the wafer translator 10. In some embodiments, the pitch between the adjacent wafer-side contact structures 16 can be p₁ in the horizontal direction and p₂ in the vertical direction. The width and height of the wafer-side contact structures 16 (“characteristic dimensions”) are denoted as d₁ and d₂. In some embodiments, the wafer-side contact structures 16 can be pins that touch corresponding die contacts on the wafer 30 (FIG. 1A). In general, the size/pitch of the inquiry-side contact structures 14 is larger than the size/pitch of the wafer-side contact structures 16, therefore improving alignment and contact between the test contactor and the wafer translator.

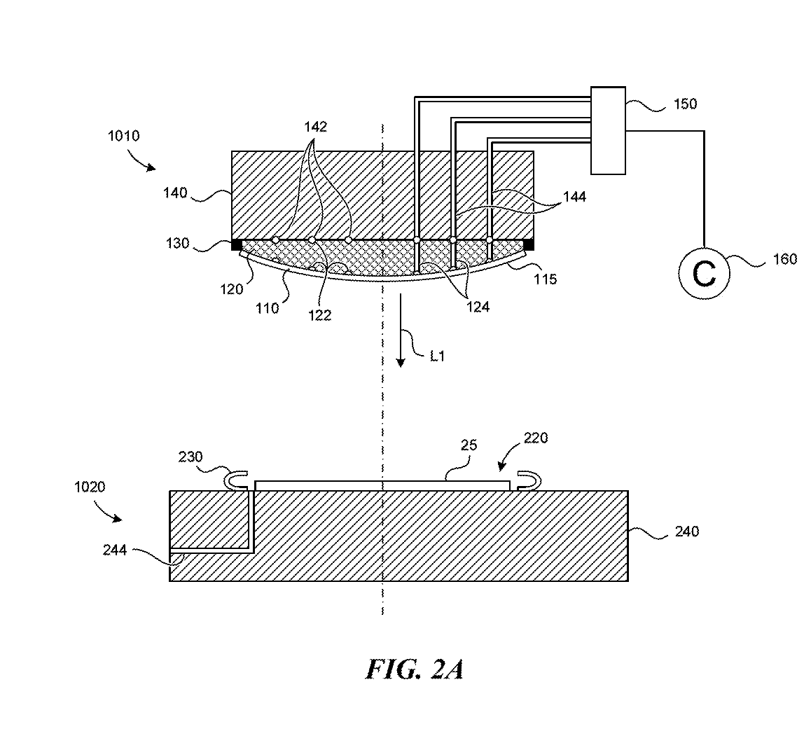

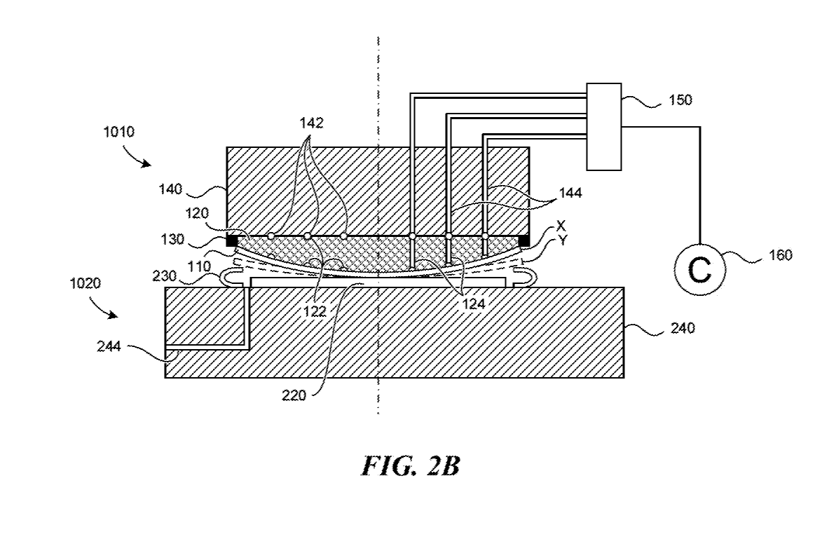

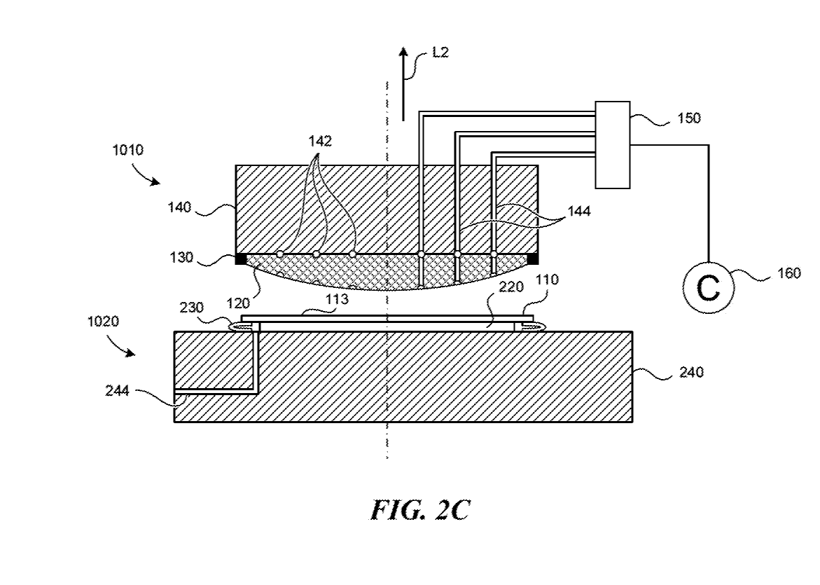

FIGS. 2A-2C are side, cross-sectional views of a test stack for testing semiconductor wafers in accordance with an embodiment of the presently disclosed technology. FIG. 2A illustrates first and second assemblies 1010 and 1020. The first assembly 1010 includes a wafer translator 110, an insert 120 (e.g., an elastomer), a wafer translator chuck 140, an interface gasket 130, a vacuum source 150, and a controller 160. The second assembly 1020 includes a wafer chuck 240, a wafer 220, and a wafer chuck gasket 230.

In some embodiments, the vacuum source 150 is connected to the wafer translator 110 through evacuation paths 144 in the wafer translator chuck 140 and evacuation paths 124 in the insert 120. In some embodiments, the evacuation paths 144/124 can be drilled, and in other embodiments, other suitable manufacturing methods (e.g., molding) are used. The evacuation paths 144 may be connected to one or more corresponding chuck grooves 142 and corresponding insert grooves 122 for a uniform distribution of the vacuum over the surface of the wafer translator 110. For example, the grooves 142/122 can be circular, resulting in concentric rings of vacuum at the interfaces between the wafer translator chuck 140 and the interface 120, and between the wafer translator 110 and the interface 120. In some embodiments, the vacuum rings can improve the holding force of the vacuum because the rings increase the applied area of the vacuum. Three evacuation paths 144/124 are shown for purposes of illustration, and other suitable numbers and configurations of the evacuation paths are used in other embodiments. A controller 160 can control the operation of the system shown in FIG. 2A, including the application and release of the vacuum. In some embodiments, the vacuum in the evacuation paths 144/124 can be individually controlled by the controller 160.

In at least some embodiments, the wafer translator 110 is sufficiently deformable (e.g., flexible) in a direction L1 to approximate the convex shape of the insert 120 (e.g., the wafer translator bows or curves away from the translator chuck). In some embodiment, the insert 120 can be curved about 0.1-6 mm or 1-5 mm away from the translator chuck when testing 300 mm wafers. In at least some embodiments, the curvature of the insert 120 exceeds a size of manufacturing imperfections of the translator chuck (e.g., manufacturing-induced roughness, out of planarity tolerance, etc.). In some embodiments, the insert 120 can be made of an elastomer with enough porosity to compress the material under pressure. In some embodiments, the insert 120 and the wafer translator chuck 140 can be combined into one unit by, for example, permanently attaching the insert 120 to the wafer translator chuck 140, or by manufacturing the wafer translator chuck 140 and the insert 120 as an integral unit from the same elastomer stock. In some embodiment, the wafer translator chuck 140 may have a curved outer surface facing the insert 120. In some embodiments, the gasket 130 can prevent vacuum losses (e.g., for a sponge-like insert 120) and/or can keep the insert 120 centered. In operation, the assembly 1010 can be moved in the direction L1 toward the assembly 1020 to bring the wafer translator 110 in contact with the wafer 220.

FIG. 2B illustrates the wafer translator 110 contacting the wafer 220. In at least some embodiments, the wafer translator 110 can be gradually brought into contact with the wafer 220 such that a center section of the wafer translator 110 contacts the wafer 220 first (e.g., position of the wafer translator 110). Due to compressibility of the insert 120 and deformability of the wafer translator 110, the contact area between the wafer translator 110 and the wafer 220 may gradually spread from the center of the wafer translator radially outwardly, e.g., as the wafer 220 assumes position Y due to the relative motion of the first and second assemblies, 1010, 1020. In at least some embodiments, this gradual conformance of the convex wafer-side surface of the wafer translator 110 to the active side of the wafer 220 can minimize or at least reduce trapped gas between the wafer translator 110 and the wafer 220. Because gas bubbles can prevent/reduce electrical contact between the wafer translator and the wafer, reducing or eliminating gas bubbles can significantly improve the result of the test operation.

As the first assembly 1010 contacts the wafer 220, the controller 160 may start reducing vacuum in the evacuation paths 144/124. For example, when the wafer translator 110 generally conforms to the active surface of the wafer 220 beyond the radial position of the innermost groove 122, the vacuum in the innermost evacuation paths 144/122 can be reduced or eliminated, and the process can be repeated for the outwardly located grooves 122 until the vacuum is released for all the evacuation paths 144/122. In at least some embodiments, this controlled release of vacuum may improve the alignment and reduce the incidence of gas bubbles between the wafer translator 110 and the wafer 220.

FIG. 2C illustrates the wafer translator 110 in operational contact with the wafer 220. In some embodiments, vacuum can be applied through a vacuum path 244 in the wafer chuck 240 to hold the wafer translator 110 in contact with the wafer 220. A wafer chuck gasket 230 can maintain a vacuum at the interface between the wafer-side of the wafer translator 110 and the wafer/wafer chuck. In some embodiments, mechanical clamping or adhesion is used to maintain contact between the wafer translator 110 and the wafer 220. In some embodiments, the first assembly 1010 can be moved away in a direction L2 after the wafer translator 110 is secured in contact with the wafer 220 (e.g., by applying a vacuum to the wafer translator 110 via the vacuum path 244), and the test contactor (not shown) may be brought into contact with the inquiry-side 113 of the wafer translator 110 for wafer testing (e.g., DUT testing). In general, the reduced incidence of the gas bubbles between the wafer translator 110 and the wafer 220 improves the testability of the DUTs by reducing electrical resistance between the wafer translator and the wafer.

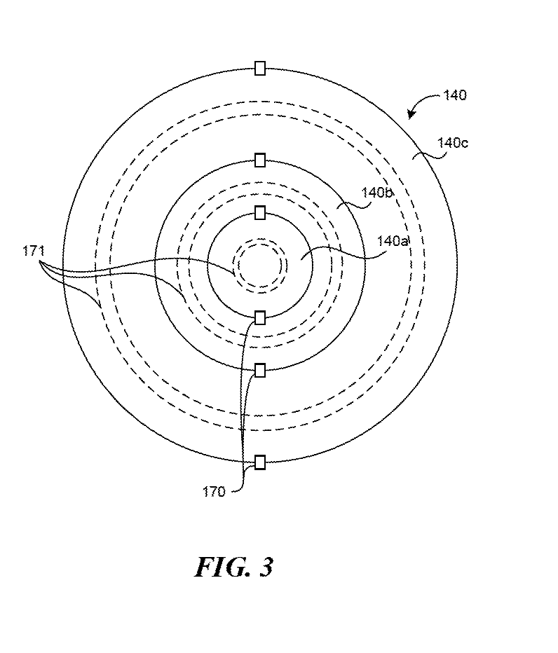

FIG. 3 is a partially schematic, bottom view of a wafer translator chuck 140 configured in accordance with another embodiment of the presently disclosed technology. In a particular aspect of this embodiment, the wafer translator chuck 140 is segmented into radial segments, e.g., radial segments 140a-140c. In some embodiments, actuators 171 can move the radial segments 140a-140c in and out of a principal plane of the wafer translator chuck (e.g., in and out of the plane of FIG. 3) using linear bearings 170 to slide the radial segments 140a-140c in and out of the principal plane. In the illustrated embodiment, the actuators 171 are behind the radial segments 140a-140c and may be attached to a fixed surface (not shown) to support moving the radial segments 140a-140c. For example, the centrally located radial segment 140a may be moved out of the plane by a first distance, an adjacent radial segment 140b may be moved out of the plane by a smaller, second distance, and so on to approximate a convex shape of the outer surface of the wafer translator chuck 140. Three radial segments 140a-140c are illustrated in FIG. 3, and in other embodiments other number of radial segments are used. As a result, the wafer translator that is attached to the wafer translator chuck 140 may approximate the convex shape of the outer surface of the wafer translator chuck. In some embodiments, the segmentation of the wafer translator chuck 140 may eliminate or reduce a need for the insert 120. In operation, the wafer translator can be brought into contact with the wafer by, for example, starting from the most extended central location (corresponding to the radial segment 140a of the wafer translator chuck), followed by a sequence of the portions of the wafer translator having a progressively greater distance from the central location. In at least some embodiments, the sequential contact between segments of the wafer translator and the wafer is expected to reduce or eliminate the incidence of gas bubbles trapped between the wafer translator and the wafer.

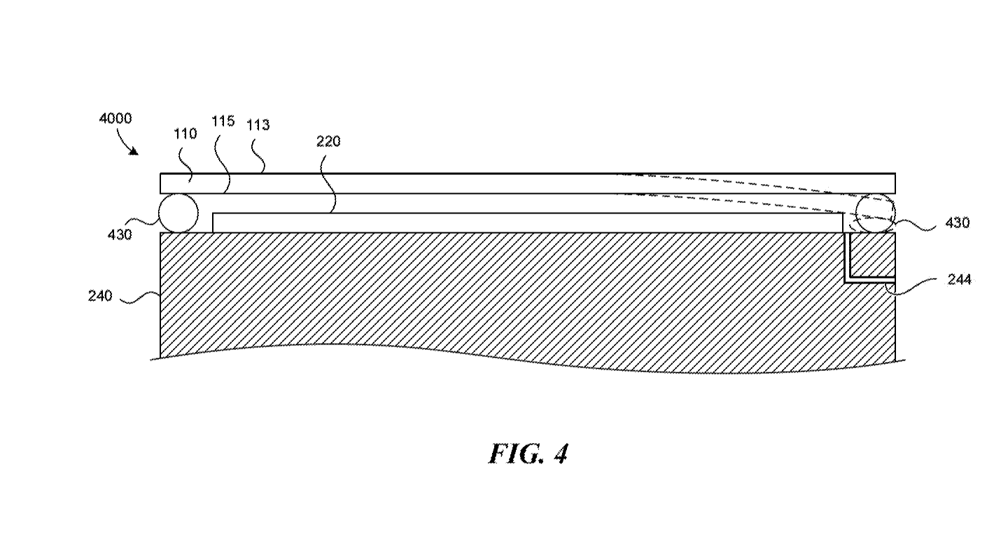

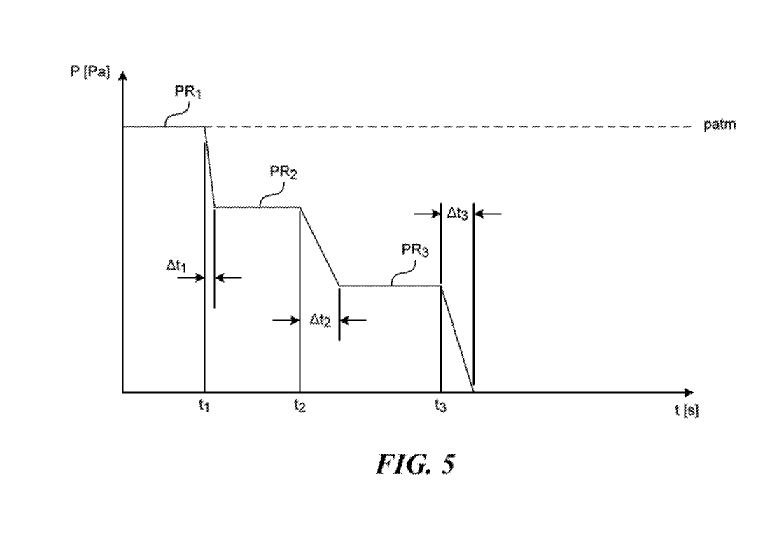

FIG. 4 is a partially schematic, side view of a translator stack 4000 configured in accordance with another embodiment of the presently disclosed technology. The translator stack 4000 includes the wafer translator 110, the wafer 220, a gasket 430 and the wafer chuck 240. In some embodiments, after the wafer translator 110 is positioned against the wafer 220, a vacuum pulls the wafer-side 115 of the wafer translator 220 into contact with the active side of the wafer 220. In some embodiments, the vacuum can be applied through an evacuation path 244. However, a relatively rapid drop in pressure between the wafer translator and the wafer can cause an uneven contact between the wafer-side 115 and the wafer 220. For example, the vacuum between the wafer translator and the wafer may increase faster in the vicinity of the evacuation path 244, and slower in the area that is away from the evacuation path 244. As a result, the wafer translator 110 may bend unevenly, thereby reducing the accuracy of the alignment between the wafer translator 110 and the wafer 220. In some embodiments, the accuracy of the alignment between the wafer translator 110 and the wafer 220 can be improved using methods described with reference to FIG. 5 below.

FIG. 5 is a graph of the vacuum between a wafer translator and a wafer chuck as a function of time in accordance with an embodiment of the presently disclosed technology. The horizontal axis represents time, and the vertical axis represents the pressure of a gas between the wafer translator and the wafer. In some embodiments, the pressure between the wafer translator and the wafer can be decreased incrementally (via vacuum), followed by a period of time when the pressure remains relatively constant. Decreasing the pressure incrementally (e.g., in phases) is expected to promote spatial uniformity of the vacuum, and may decrease or eliminate unevenness of the contact between the wafer translator and the wafer. For example, prior to applying the vacuum, the pressure between the wafer translator and the wafer can be atmospheric pressure (patm or PR1). Next, the pressure can be decreased to PR2 during a period of time Δt1 (e.g., 0.1-2 seconds). The pressure between the wafer translator and the wafer may remain generally constant at PR2 during a pressure stabilization period (e.g., 1-10 seconds, extending to a start of a period of time Δt2), followed by a decrease in pressure to PR3 over a period of time Δt2, followed by another generally constant pressure stabilization period at pressure PR3. In at least some embodiments, the uniformity of contact between the wafer-side of the wafer translator and the active side of the wafer can be improved by increasing the vacuum in phases.

From the foregoing, it will be appreciated that specific embodiments of the technology have been described herein for purposes of illustration, but that various modifications may be made without deviating from the disclosure. For example, in some embodiments, the gasket 130 can have a slightly undersized diameter to deform the wafer translator into a convex shape (e.g., an inner diameter of the gasket can be slightly smaller than an outer diameter of the wafer translator). Furthermore, the gasket 130 can be adhesive or tacky (e.g., releasably adhesive) to improve the retention of the gasket against the wafer translator chuck and/or the translator. In various embodiments, pairs of components can be moved toward each other by moving one or both components (e.g., the wafer translator chuck 140 can be moved toward the wafer chuck 240, or the the wafer chuck 240 can be moved toward the wafer translator chuck 140, or both components can be moved into a contact). Moreover, while various advantages and features associated with certain embodiments have been described above in the context of those embodiments, other embodiments may also exhibit such advantages and/or features, and not all embodiments need necessarily exhibit such advantages and/or features to fall within the scope of the technology. Accordingly, the disclosure can encompass other embodiments not expressly shown or described herein.

I/We claim:

1. An apparatus for testing semiconductor dies, comprising:
a wafer translator having a wafer-side positioned to face toward a device under test, and an inquiry-side facing away from the wafer side; and
a wafer translator chuck configured to carry the wafer translator in a curved orientation.

2. The apparatus of claim 1, further comprising an insert between the wafer translator and the translator chuck.

3. The apparatus of claim 2 wherein the insert is attached to the wafer translator chuck.

4. The apparatus of claim 2 wherein the insert is integral with the wafer translator chuck.

5. The apparatus of claim 2 wherein the insert is made at least in part of a porous elastomer.

6. The apparatus of claim 2 wherein the insert and the wafer translator are made of an elastomer.

7. The apparatus of claim 2 wherein the wafer translator chuck includes a curved surface facing the insert.

8. The apparatus of claim 2, further comprising:
a source of vacuum;
a plurality of evacuation paths connecting the source of vacuum and the wafer translator; and
a controller configured to change the vacuum in one of the evacuation paths.

9. The apparatus of claim 2, further comprising a gasket disposed peripherally about the insert.

10. The apparatus of claim 1, further comprising a gasket disposed peripherally about the wafer translator, wherein an inner diameter of the gasket is smaller than the outer diameter of the wafer translator.

11. The apparatus of claim 10 wherein the gasket includes an adhesive surface facing the wafer translator chuck.

12. The apparatus of claim 1 wherein the wafer translator chuck includes a plurality of concentric segments configured to move in and out of a principal plane of the wafer translator chuck.

13. The apparatus of claim 1, further comprising:
a wafer chuck;
a wafer carried by the wafer chuck, wherein an active surface of the wafer faces the wafer translator; and
a wafer chuck gasket disposed peripherally about the wafer.

14. The apparatus of claim 13 wherein:
a central portion of the wafer translator contacts the wafer, and
a peripheral portion of the wafer translator does not contact the wafer.

15. The apparatus of claim 1 wherein the wafer-side of the wafer translator carries contact structures having a first scale, and an inquiry-side of the wafer translator carries the contact structures having a second scale, wherein the first scale is smaller than the second scale.

16. An apparatus for testing semiconductor dies, comprising:
a wafer translator chuck having a first side configured to face a wafer; and
an insert at the first side of the wafer translator chuck, the insert having a first surface configured to face the wafer, wherein the first surface is curved toward the wafer.

17. The apparatus of claim 16, further comprising a wafer translator having a wafer-side positioned to face toward a device under test, and an inquiry-side facing the first surface of the insert.

18. The apparatus of claim 17, further comprising a wafer having an active side to face toward the wafer translator.

19. The apparatus of claim 16 wherein the insert is attached to the wafer translator chuck.

20. The apparatus of claim 16 wherein the insert is integral with the wafer translator chuck.

21. A method for testing a device under test, comprising:
securing a wafer translator against a wafer translator chuck in a bowed position, the wafer translator having a wafer-side positioned to face toward a wafer, and an inquiry-side facing away from the wafer side;
moving the wafer translator chuck toward the wafer; and
contacting the wafer with a central portion of the wafer translator.

22. The method of claim 21, further comprising:
after contacting the wafer with the central portion of the wafer translator, contacting the wafer with peripheral portions of the wafer translator.

23. The method of claim 21, further comprising:
conforming a shape of the wafer translator to approximate a shape of an insert configured between the wafer translator chuck and the wafer translator.

24. The method of claim 21, further comprising:
disposing a gasket peripherally about the wafer translator.

25. The method of claim 24 wherein an inner diameter of the gasket is smaller than an outer diameter of the wafer translator, and wherein the wafer-side of the wafer translator is curved away from the wafer translator chuck in response to a difference between the inner diameter of the gasket and the outer diameter of the wafer translator.

26. The method of claim 21 wherein the wafer-side of the wafer translator chuck includes a plurality of concentric segments attached to a corresponding plurality of actuators being configured to curve the wafer translator by moving the segments in and out of a principal plane of the wafer translator chuck.

27. The method of claim 21, further comprising:
applying a vacuum in evacuation paths connecting a source of vacuum with central and peripheral portions of wafer translator;
reducing the vacuum at the central portion of the wafer translator; and
after reducing the vacuum at the central portion of the wafer translator, reducing the vacuum at the peripheral portion of the wafer translator.

28. The method of claim 22, further comprising testing a device under test, wherein the device under test is a die of the wafer.

29. A method for testing a device under test, comprising:
positioning a wafer translator against a wafer chuck, the wafer translator having a wafer-side positioned to face toward a wafer, and an inquiry-side facing away from the wafer side;
evacuating a gas between the wafer translator and the wafer chuck in a plurality of steps to increase a vacuum; and
holding the vacuum generally constant between the steps.

30. The method of claim 29 wherein the wafer-side of the wafer translator carries contact structures having a first scale, and an inquiry-side of the wafer translator carries the contact structures having a second scale, wherein the first scale is smaller than the second scale.

31. The method of claim 29, further comprising testing a device under test, wherein the device under test is a die of the wafer.

32. The method of claim 29, further comprising compressing a wafer chuck gasket between the wafer translator and the wafer chuck.
